(19) United States
(12) Patent Application Publication
(10) Pub. No.: US 2024/0059895 A1
(43) Pub. Date: Feb. 22, 2024

(54) CURABLE SILICONE COMPOSITION, CURED PRODUCT OF SAME, AND LAMINATE

(71) Applicant: DOW TORAY CO., LTD., Shinagawa-ku, Tokyo (JP)

(72) Inventor: Masaaki AMAKO, Ichihara-shi, Chiba (JP)

(21) Appl. No.: 18/268,224

(22) PCT Filed: Dec. 14, 2021
(86) PCT No.: PCT/JP2021/046131

§ 371 Date: Jun. 17, 2023

(30) Foreign Application Priority Data
Dec. 25, 2020 (JP) 2020-216519

(51) Int. Cl. C08L 83/04; C08J 3/20; B32B 17/10

(52) U.S. Cl. CPC C08L 83/04; C08J 3/20; B32B 17/10; C08J 2383/04; C08J 2483/04; C08L 2205/025; B32B 2383/00; B32B 2307/748

(57) ABSTRACT

Provided is a curable silicone composition with hot-melt properties, cured product thereof, and use thereof where organic solvent is essentially not used, in which curing using a relatively small amount of condensation reaction catalyst is feasible, side reactions before and after the curing reaction are suppressed, curing at high speed is feasible by providing favorable melt curability, and where the cured product thereof includes practically sufficient adhesive properties and mechanical characteristics. Providing a condensation reactive organopolysiloxane resin with hot-melt properties and a condensation reaction catalyst containing mixture including a condensation reaction catalyst that is liquid at 25° C. (suitably a volatile superbasic substance such as DBU) and liquid organopolysiloxane at a specific ratio, a curable silicone composition with hot-melt properties, and use of the cured product thereof. The composition may further contain solid particles such as functional filler providing a product with a functional member such as an optical member.

### TECHNICAL FIELD

The present invention relates to a curable silicone composition that has hot-melt properties being provided with favorable hot-melt curable properties and moldability (in particular transfer moldability) and can be produced and used in processes that essentially do not use organic solvent, if desired, and to a cured product thereof and laminate body containing the composition or cured product.

### BACKGROUND ART

Curable silicone compositions can be cured to form cured products having excellent heat resistance, cold resistance, electrical insulating properties, weather resistance, water repellency, and transparency, and are utilized in a wide range of industrial fields. In general, a cured product of such a curable silicone composition is less prone to discoloration compared with other organic materials, and has reduced deterioration of physical properties over time, and therefore is also suitable as an encapsulant or adhesive for optical materials and semiconductor devices.

In particular, in recent years, from the perspective of ease of use and cost reduction in the manufacturing of light emitting devices, curable silicone compositions with hot-melt properties have become widely used. For example, the patent applicants have proposed curable silicone compositions with hot-melt properties in tablet form and sheet form cured through a hydrosilylation reaction having superior over-molding moldability in Patent Document 1 and Patent Document 2. These curable silicone compositions have superior meltability and curability/moldability as an encapsulant, but use of an organic solvent such as toluene or the like in the manufacturing process thereof is essential, and therefore there are cases where application to a transfer molding process or the like where rapid curing after heating and melting is required may not be feasible.

On the other hand, Patent Document 3 proposes a curable composition having melt processability containing a so-called resin linear type organosiloxane block copolymer and diazabicycloundecene (DBU) or the like super strong base catalyst (condensation reaction catalyst). However, the condensation reaction type curable composition must use a large amount of condensation reaction catalyst to not lose melt curability, but when a large amount of condensation reaction catalyst is used, the condensation reactive organopolysiloxane resin may polymerize due to side reactions impairing hot-melt properties or melt curability, undesired condensation reactions may occur after the curing reaction, physical properties of the cured product may be reduced, a phenyl group in the organopolysiloxane resin with hot-melt properties may be cleaved by a superbasic catalyst, or benzene or the like may be generated. In particular, if a superbasic catalyst (condensation reaction catalyst) such as the aforementioned DBU is used in a cure system including a functional filler such as solid particles or pigment, there are cases when this functional filler impairs curing so that providing sufficient melt curability from a practical standpoint requires a large amount of condensation reaction catalyst or pre-processing of the functional filler using a solvent, and this has caused problems in suppressing side reactions in process design. Furthermore, application to processes where use of an organic solvent is not required had not been sufficiently achieved. Note that Patent Document 4 proposes combining a specific quaternary ammonium salt to suppress generation of benzene caused by cleavage of the phenyl group in the organopolysiloxane resin, but does not reduce the amount of condensation reaction catalyst used nor suppress hindering of curing, and so was not able to achieve low usage of condensation reaction catalyst nor a curable silicone composition provided with sufficient melt curability.

### BACKGROUND ART DOCUMENTS

### Patent Documents

[Patent Document 1] International Patent Publication WO 2018/030287
[Patent Document 2] International Patent Publication WO 2018/030288
[Patent Document 3] Japanese Unexamined Patent Application Publication (Translation of PCT Application) No. 2015-505896
[Patent Document 4] International Patent Publication WO 2020/060702

### SUMMARY OF THE INVENTION

### Problem to be Solved by the Invention

In order to resolve the problems described above, an object of the present invention is to provide a curable silicone composition with hot-melt properties, cured product thereof, and use thereof where organic solvent is essentially not used, curing using a relatively small amount of condensation reaction catalyst is feasible, side reactions before and after the curing reaction are suppressed, curing at high speed is feasible by providing favorable melt curability, and where the cured product thereof includes practically sufficient adhesive properties and mechanical characteristics.

### Means for Solving the Problem

As a result of intensive investigation, the present inventors found that a curable silicone composition with hot-melt properties including: a condensation reactive organopolysiloxane resin with hot-melt properties, and a condensation reaction catalyst-containing mixture containing a specific ratio of condensation reaction catalyst (suitably a volatile superbasic substance such as DBU) and an organopolysiloxane that are liquid at 25° C. resolves the problems described above and arrived at the present invention. This composition may also contain solid particles and in particular, use of functional fillers enables imparting a cured product that is a functional member such as an optical member.

### Effect of the Invention

In the present invention, use of a mixture containing condensation reaction catalyst composed of the aforementioned liquid components suppresses interaction between the condensation reaction catalyst such as DBU and the surface of the powder or the like enabling providing a curable silicone composition with hot-melt properties having favorable melt curability while using a relatively small amount of condensation reaction catalyst. In addition, the mixture containing condensation reaction catalyst according to the present invention is liquid so use of organic solvent is substantially unnecessary in the manufacturing process or during use of the curable silicone composition according to the present invention, in other words enabling a solvent free composition and process. Furthermore, the curable silicone composition with hot-melt properties according to the present invention is provided with favorable melt curability even if solid particles such as a functional filler are included and in addition to rapid curing and sufficient adhesive characteristics and mechanical characteristics for use, this enables providing a cured product including physical properties derived from the functional filler (for example, hardness, color, optical transmittance, light reflectance, light scattering, wavelength conversion, thermal conductivity, electrical conductivity, and the like). In addition, the curable silicone composition according to the present invention has superior transfer moldability and enables providing a laminate body including this composition, cured to produce a cured product, and uses thereof.

### DESCRIPTION OF THE PREFERRED EMBODIMENTS

Embodiments of the present invention will be described below in detail.

### Hot Melt Properties

Component (A) and curable silicone composition according to the present invention exhibit hot-melt properties. Specifically, exhibiting non-flowability at 25° C. and a complex melt viscosity of 500,000 Pa·s or less at 130° C. Non-fluid refers to not flowing in a no-load state, for example, the state of being lower than the softening point measured by the softening point testing method in the ball and ring method of hot-melt adhesives specified in “Testing methods for the softening point of hot-melt adhesives” of JIS K 6863-1994. That is, in order to be non-fluid at 25° C., the softening point must be higher than 25° C. Component (A) preferably has a complex melt viscosity at 130° C. of 200 Pads or less, 100 Pa·s or less, 50 Pa·s or less, 20 Pa·s or less, or is within the range of 0.10 to 20 Pa·s. Moreover, when the melt viscosity at 130° C. is within the range described above, the adhesiveness of the cured product or molded product after being hot-melted and then cooled to 25° C. is favorable. In addition, use of component (A) with the melt viscosity described above of 0.10 to 15 Pa·s may enable suppressing deformation or peeling of the cured product after transfer mold processing.

Herein, “having hot-melt properties” means that the overall composition has a high viscosity (including a raw rubber-like state in which plasticity can be measured) or is in a solid state to the extent that the shape can be retained at 25° C., but has a melt viscosity in the range described later at 130° C., and the material is softened and becomes flowable upon heating. Conversely, “not having hot-melt properties” means that the composition or component (solid organopolysiloxane resin or the like) does not exhibit heating and melting behavior independently at 200° C. or lower, and specifically means that the component does not have a softening point or melt viscosity at a temperature of 200° C. or lower.

### Curable Silicone Composition

The curable silicone composition according to the present invention contains:
(A) an organopolysiloxane resin having a glass transition temperature (Tg) of 25 to 130° C. containing a siloxane unit expressed by RSiO_{3/2} (where R represents an alkyl group having 1 to 20 carbon atoms or an aryl group having 6 to 14 carbon atoms which may be substituted with a halogen atom) or SiO_{4/2} in the molecule and at least one of a condensation reactive functional group and an aromatic functional group in the molecule, and
(B) a mixture containing condensation reaction catalyst of component (B1) and component (B2) described below pre-mixed at a mass ratio of 1:99 to 90:10, wherein
(B1) is a condensation reaction catalyst that is liquid at 25° C.,
(B2) is a chain or cyclic organopolysiloxane that is liquid at 25° C. and has a degree of polymerization of siloxane in the range of 3 to 50, and the overall composition is non-flowable at 25° C. while having hot-melt properties.

The composition may contain (C) solid particles, and may be blended with other additives (for example, an adhesion imparting agent, or the like) as long as the technical effects of the present invention are not impaired. However, an object of the present invention is to be organic solvent free so preferably substantially no organic solvents are used in the manufacturing and use thereof. Specifically, the content of organic solvent is less than 5% by mass of the entire composition, suitably less than 1% by mass, and particularly preferably below the detection limit (less than 0.1% by mass).

### Component (A)

Component (A) is the main ingredient of the present composition, and when component (C) is included, it is a component that serves as a binder for the functional powder/filler. Specifically, component (A) contains a siloxane unit called a T unit or a Q unit, and has a condensation reactive functional group and an aromatic functional group in the molecule and therefore has a high refractive index and has hot-melt properties, and has excellent moldability and can be rapidly cured by a condensation reaction in the presence of component (B).

This type of component (A) has non-flowable properties at 25° C. and has a glass transition temperature (Tg) measured using a differential scanning calorimeter (DSC) in the range of 25 to 130° C.

This type of component (A) is an organopolysiloxane resin containing a siloxane unit expressed by RSiO_{3/2} (where R represents an alkyl group having 1 to 20 carbon atoms or an aryl group having 6 to 14 carbon atoms which may be substituted with a halogen atom) (hereinafter, T unit) and a siloxane unit expressed by SiO_{4/2} (hereinafter, Q unit) in the molecule and contains at least one condensation reactive functional group in the molecule and at least one aromatic functional group in the molecule.

Component (A) according to the present invention may be an organopolysiloxane resin containing a polydiorganosiloxane structure expressed by (R₂SiO_{2/2})n (hereinafter referred to as (D)n unit, where R represents an alkyl group having 1 to 20 carbon atoms or an aryl group having 6 to 14 carbon atoms which may be substituted with a halogen atom and n is a number in the range of 3 to 1000) in the molecule; and this is preferable.

The condensation reactive functional group in component (A) is preferably a hydroxyl group or an alkoxy group with 1 to 3 carbon atoms, more preferably a hydroxyl group, and even more preferably contains hydroxyl group in a range of 0.1 to 2.0% by mass in the molecule. In addition, the aromatic functional group in component (A) is the functional group that imparts hot-melt properties to component (A), that may be an aryl group having 6 to 14 carbon atoms, that in particular preferably contains a phenyl group on the T unit or the (D)n unit described next, and that in particular preferably contains phenyl groups at an amount that imparts the aforementioned hot-melt properties.

Here, the alkyl group having 1 to 20 carbon atoms or an aryl group having 6 to 14 carbon atom represented by R represents an alkyl group such as a methyl group, ethyl group, or the like or an aryl group such as a phenyl group, tolyl group, or the like, or a group with the hydrogen atoms bonded to these groups partially or fully substituted with halogen atoms such as fluorine atoms, and from the standpoint of industrial production, preferably represents a methyl group or a phenyl group.

Preferably, component (A) is a resin-linear organopolysiloxane block copolymer including: a structure in which a resin structure block containing only R^{A}SiO_{3/2} (where RA represents a monovalent organic group, a hydroxyl group, or an alkoxy group having 1 to 3 carbon atoms and of the R^{A} in the molecule at least one or more represents an aryl group having 6 to 14 carbon atoms), or optionally also containing a Q unit: a siloxane unit expressed by SiO_{4/2;} and a (D)n linear structure block expressed by (R₂SiO_{2/2})n (where n is the same number as described above and R represents the same group described above) are connected by silalkylene bonds or Si—O—Si bonds; and a R^{A}SiO_{3/2} unit. With the silalkylene bonds or Si—O—Si bonds connecting the resin structure block and the linear structure block in the polymer, the Si atoms bonded to the resin structure preferably constitute the R^{A}SiO_{3/2} unit.

The resin structure block in component (A) is a partial structure that imparts hot-melt properties to the entire component (A), and is a resinous organopolysiloxane structure. This structure forms a partial structure composed of a resinous organopolysiloxane containing an arylsiloxane unit expressed by R^{A}SiO_{3/2} as an essential unit and containing a plurality of T units or Q units bonded to one another. In particular, when multiple aryl groups such as phenyl groups are included in the molecule, the refractive index of component (A) can be increased. Preferably, component (A) is an organopolysiloxane resin containing an arylsiloxane unit expressed by R^{A}SiO_{3/2} (where R^{A} represents the same group as described above) in an amount of from 20 to 100 mass % of the entire organopolysiloxane, and from the perspective of the hot-melt properties and the refractive index described above, the resin structure is particularly preferably formed substantially solely from the arylsiloxane unit expressed by R^{A}SiO_{3/2}.

The linear structure is a block expressed by R₂SiO_{2/2})n, and is a structure in which 3 or more and preferably 5 or more diorganosiloxy units expressed by R₂SiO_{2/2} are linked in a chain. This linear structure block is an optional partial structure that imparts suitable flexibility to the solid layer formed from the organopolysiloxane resin. In the formula, n represents the degree of polymerization of the diorganosiloxy unit constituting the partial structure, which is preferably within a range of 3 to 250, more preferably within a range of 5 to 250, 50 to 250, 100 to 250, or 200 to 250. When n in the partial structure exceeds the above upper limit, the properties as a linear molecule derived from the linear structure are strongly expressed and the hot-melt properties may be insufficient.

The resin structure block and the linear structure block in component (A) may be linked by a silalkylene bond derived from a hydrosilylation reaction between an alkenyl group and a silicon atom-bonded hydrogen atom, or a Si—O—Si bond derived from a condensable reaction group at the end of the resin structure or the linear structure. In particular, in the present invention, it is particularly preferable for the Si atoms bonded to the resin structure to constitute an R₁SiO_{3/2} unit, and it is particularly preferable to have the following partial structure (T-Dn). From an industrial perspective, at least a portion of the R₁ preferably represent a phenyl group, and R preferably represents a methyl group or a phenyl group.

Moiety structure (T-Dn)

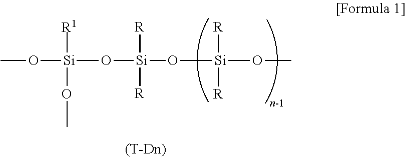

Preferably, in the above partial structure, the end of the left Si—O-bond constituting a T unit is bonded to a hydrogen atom or another siloxane unit constituting the resin structure, respectively, and is preferably bonded to another T unit. On the other hand, the end of the right Si—O-bond is bonded to another siloxane unit, triorganosiloxy unit (M unit), or a hydrogen atom that forms a linear structure or a resin structure. Needless to say, a silanol group (Si—OH) is formed when a hydrogen atom is bonded to the end of the Si—O-bond.

From the standpoint of hot-melt properties and condensation reactive properties, component (A) is in particular preferably an organopolysiloxane resin expressed by the following siloxane unit formula: {Si(Me)₂O_{2/2}}a{Si(Me)(Ph)O_{2/2}}b{Si(Ph)₂O_{2/2}}c{Si(Me)O_{3/2}}d{Si(Ph)O_{3/2}}e(OH)f

In the formula, Me represents a methyl group, Ph represents a phenyl group, a+b+c+d+e is 1.0, each of a to e is a number that may be 0, and a+b+c is a number in the range of 0 to 0.5, preferably in the range of 0 to 0.4, d+e is a number in the range of 0.5 to 1.0, preferably in the range of 0.6 to 1.0, b+c+e is a positive number, suitably e is a number in the range of 0.3 to 1.0, and f is a number such that the amount of hydroxyl groups in the organopolysiloxane resin in the formula described above is in the range of 0.1 to 2.0% by mass, suitably 0.1 to 1.0% by mass. When a+b+c+d-0, the component (A) is a phenyl-containing T-resin composed only of Si(Ph)O_{3/2} and a hydroxyl group.

### Component (B)

Component (B) is one of the characteristic structures of the present invention, and is a condensation reaction catalyst containing a mixture composed of (B1) a condensation reaction catalyst that is liquid at 25° C. and (B2) a chain or cyclic organopolysiloxane having a degree of polymerization of siloxane in the range of 3 to 50 premixed at a mass ratio of 1:99 to 90:10 and that is a liquid at 25° C.

### Technical Significance of Using a Pre-Mixture

The condensation reaction catalyst must be liquid to enable uniform mixing of component (A) that is non-flowable but can undergo a condensation reaction upon heating and the condensation reaction catalyst at room temperature (25° C.) is substantially without using an organic solvent. In addition, from the standpoint of controllability of the reaction and suppression of side reactions, this type of condensation catalyst is preferably such that as small a quantity as possible is added with removal from the cured product being possible through volatilization or the like by heating during the curing reaction.

A super strong base catalyst such as diazabicycloundecene (DBU) proposed in aforementioned Patent Document 3 is preferable a condensation reaction catalyst that satisfies these conditions. These superbasic catalysts, particularly diazabicyclic compounds represented by DBU and guanidine compounds represented by tetramethylguanidine (TMG), may impair melt curability unless used in large amounts. In particular, in systems containing solid particles such as functional fillers, a large amount exceeding 3000 ppm relative to the solid content of the composition must be added. If a large amount of condensation reaction catalyst is added to the curable silicone composition with hot-melt properties, the condensation reactive organopolysiloxane resin will polymerize due to a side reaction before curing, resulting in poor hot-melt and melt-curing properties. In addition, the condensation reaction catalyst may not be sufficiently deactivated or removed even by heating during curing, leading to unintended condensation reactions or reverse reactions occurring after the curing reaction, and to a strong concern of possible deterioration of the physical properties of the cured product.

Using means such as nuclear magnetic resonance, the inventors have confirmed that the behavior of this type of super strong base catalyst causes interaction between the super strong base catalyst (DBU and the like) and the surface of the solid phase (solid organopolysiloxane resin, solid particles, functional filler such as pigments, and the like), leading to inhibition of curing. Pretreatment of the functional filler using an organic solvent to suppress this inhibition of curing can be considered but this would cause one of the objects of the present invention, being organic solvent free, to not be achieved, and in addition, the effect thereof is limited (see Comparative Example 2 below).

The present inventors found that pre-dispersion of the super strong base catalyst (DBU or the like) in organopolysiloxane that is liquid and at a relatively low degree of polymerization and use in a pre-mixed state suppresses interaction of the super strong base catalyst and the solid phase, thus melt curability is not impaired even if a relatively low amount is added, and curing a system containing solid particles of component (A) and optionally component (C) at high speed is feasible. The mechanism thereof is anticipated to be that the super strong base catalyst (DBU and the like) is stabilized by coordination or intermolecular interaction with the organopolysiloxane having a low degree of polymerization, further stabilized by coordination with the solid state silicone of component (A), and that curing inhibition is suppressed by interaction with solid particles (C). In particular, as indicated in the Examples and the like below, compared to adding the super strong base catalyst (DBU and the like) described above alone, including a solid phase functional filler or the like prevents impairment of melt curability of the curable silicone composition with hot-melt properties even if a small amount of condensation catalyst of ⅕ or less is used in the premix, and is therefore extremely effective when the cured product thereof is used in electronic components, heat dissipation materials, semiconductor members, optical semiconductor material, optical materials, and the like. Note that by optimizing the amount of component (B1) and component (B2) with that of the overall composition, the amount of condensation reaction catalyst used can be set to 1/15 or less or 1/20 or less.

### Component (B1)

Component (B1) is a condensation reaction catalyst that is liquid at 25° C. and examples include: components selected from organic super strong bases, organic metal super strong bases, and inorganic super strong bases, represented by the “super strong base catalyst” in Patent Document 1. In particular, from the perspective of easily removing from the system after the curing reaction, use of a volatile organic super strong base as the condensation reaction catalyst is preferable. Note that the term “liquid at 25° C.” means that the condensation reaction catalyst itself has flowability, and can be homogeneously dispersed in a solid phase using mechanical force without using an organic solvent.

In the present invention, examples of a preferable component (B1) include: a diazabicyclic compound selected from diazabicycloundecene (DBU), diazabicyclononane (DBN), and diazabicyclooctane (DABCO); and a guanidine compound selected from tetramethylguanidine (TMG), N-triazabicyclodecene (TBD), and methyltriazabicyclodecene (MTBD), and these condensation reaction catalysts may be used alone or in combination. The use of DBU is particularly preferred in terms of handling workability in industrial production, liquid and volatile properties, and the like.

### Component (B2)

Component (B2) is a chain or cyclic organopolysiloxane that is liquid at 25° C. and has a degree of polymerization of siloxane in the range of 3 to 50 and by coordinating or interacting with component (B1), reduces the interaction between component (B1) and the solid phase (mainly solid particles and solid organopolysiloxane resin), and enables component (B1) to be homogeneously dispersed in the solid phase by mechanical force. If simply increasing the dispersibility of the component (B1) in the composition, an organic solvent such as toluene can be used but, differing from pre-mixing with organopolysiloxane with a low degree of polymerization, use of an organic solvent does not sufficiently suppress interaction between component (B1) and the solid phase; therefore, the technical effect of the present invention can not be achieved.

Component (B2) is preferably of low volatility or non-volatility, unlike component (B1). Component (B2) is a component that coordinates or interacts with component (B1) so if highly volatile, component (B2) will volatilize from the system leaving component (B1) in a “bare” state; therefore, there are cases where the technical effect of the present invention can not be achieved.

The organopolysiloxane in component (B2) is preferably an organopolysiloxane having a monovalent hydrocarbon group, a silicon atom-bonded hydrogen atom, an alkoxy group, and a silanol group and preferably includes an alkyl group, an aryl group, an alkenyl group, an aralkyl group, a (meth)acryloxy group, a halogenated alkyl group, an alkoxy group, a silanol group, a hydrogen atom, or the like bonded to the silicon atom constituting the polysiloxane.

More specifically, this type of component (B2) is an organopolysiloxane expressed by the structural formula: (SiR²₂O)ₖ₁ (where, each R² independently represents an alkyl group, an aryl group, or a silanol (OH) group, and k1 is a number in the range of 3 to 50), a straight chain diorganopolysiloxane expressed by the structural formula: R³₃SiO(SiR³₂O)ₖ₂SiR³₃ (where, each R³ independently represents an alkyl group, an aryl group, or a silanol (OH) group and k2 is a number in the range of 1 to 48), or a branched chain organopolysiloxane having a small number of branch units (T units or Q units) and a degree of polymerization of siloxane in the range of 3 to 50.

From the viewpoints of industrial applicability, nonvolatility, affinity with component (A), and technical effect of the invention, suitable component (B2) examples include: cyclic phenylmethylsiloxane with an average degree of polymerization of siloxane of 3 to 20, cyclic (phenylmethylsiloxane) (dimethylsiloxane) copolymer, cyclic diphenylsiloxane, dimethylsilanol siloxy terminated polyphenylmethylsiloxane expressed by the structural formula: HO—(SiPhMe—O)ₖ₃—H (where, k3 is a number in the range of 4 to 45), and dimethylsilanol siloxy terminated polydimethylsiloxane expressed by the structural formula: HO—(SiMe₂—O)ₖ₃—H. These may be used independently or in combination of two or more.

### Mixing Ratio and Premixing Means

In component (B), the pre-mix ratio of component (B1) and component (B2) is in the range of a mass ratio of 1:99 to 90:10, preferably a mass ratio of 1:99 to 85:15. If the amount of component (B1) is too small, the concentration of the condensation reaction catalyst will be too low, and the curing reactivity and curing rate may decrease. If the amount of component (B2) is too small, the interaction with component (B1) will be insufficient, and the melt curability of the composition as a whole may be impaired. Note that both are liquid at 25° C., and are preferably homogenously mixed using a known mixing means such as a mixer. If another component constituting the present invention, in particular, the (C) solid particles come into contact with component (B1) first, even if component (B2) is subsequently mixed in, the technical effect of the present invention may not be sufficiently achieved.

With the present invention, the amount of component (B) is not in particular restricted but is preferably in an amount such that the content of the condensation reaction catalyst that is component (B1) is 1000 ppm or less relative to the composition as a whole (solid content). For example, favorable melt curability can be achieved if the pre-mix described above is used as component (B) such that the content of condensation reaction catalyst in the composition is in a range of 50 to 1000 ppm, preferably 100 to 1000 ppm.

### Component (C)

Component (C) is a solid particle and is an optional constituent of the present invention, that in particular, is added for the purpose of imparting mechanical characteristics or other characteristics to the cured product, and examples include: inorganic filler, organic filler, and mixtures thereof. As described above, through use of component (B), the curable silicone composition of the present invention can achieve favorable melt curability using a relatively small amount of condensation reaction catalyst even if a large amount of component (C) is included.

There are no restrictions, in particular, with the type, function, and shape of component (C) and examples of the inorganic fillers include: reinforcing fillers, white pigment, thermally conductive fillers, electrically conductive fillers, phosphors, and mixtures of at least two of these, and examples of organic fillers include: a silicone resin filler, a fluororesin filler, and a polybutadiene resin filler. Note that the shape of these fillers is not particularly limited and may be spherical, spindle-shaped, flat, needle-shaped (fibrous), amorphous, or the like.

With the present invention, at least a part of component (C) is preferably one or more types selected from (CS) spherical solid particles, (CF) fibrous solid particles, and (CP) pigment or phosphor particles. In particular, from the perspective of improving the mechanical strength of the cured product, at least a part of component (C) is a (CS) spherical solid particle.

Reinforcing fillers may be added to improve the mechanical strength of the cured product, to improve protection and adhesion, and to maintain a solid particle shape as a binder filler in the curable silicone composition before curing. Examples of this type of reinforcing filler include fumed silica, precipitated silica, fused silica, calcined silica, fumed titanium dioxide, quartz, calcium carbonate, diatomaceous earth, aluminum oxide, aluminum hydroxide, zinc oxide, and zinc carbonate. These reinforcing fillers may also be surface treated with: organoalkoxysilanes such as methyltrimethoxysilane; organohalosilanes such as trimethylchlorosilane; organosilazanes such as hexamethyldisilazane; siloxane oligomers such as dimethylsiloxane oligomers capped with α,ω-silanol groups, methylphenylsiloxane oligomers capped with α,ω-silanol groups, methylvinylsiloxane oligomers capped with α,ω-silanol groups, or the like. The particle size of the reinforcing filler is not restricted, but the median diameter measured by a laser diffraction scattering type particle size distribution measurement is preferably within a range of 1 nm to 500 μm. Further, as the reinforcing filler, a fibrous filler such as calcium metasilicate, potassium titanate, magnesium sulfate, sepiolite, zonolite, aluminum borate, rock wool, glass fiber, or the like may be used.

Further, a coloring material, a white pigment, a thermally conductive filler, an electrically conductive filler, or a phosphor may be blended for the purpose of imparting other functions to the cured product obtained using the composition. Organic fillers such as silicone microparticles or the like may also be blended for the purpose of improving the stress relief properties of the cured product and the like.

A coloring material (also referred to as a pigment) is a component that colors the cured product and, in the case of black, achieves light shielding properties and the like. Components that can be used as a coloring material are not particularly restricted, and organic dyes, carbon black such as furnace black and acetylene black, iron oxide (red iron oxide), and the like can be used without particular restriction.

White pigment is a component that imparts whiteness to the cured product and improves light reflectivity, and the cured product obtained by curing the present composition with this component mixed in can be used as a light reflective material for light emitting/optical devices. Examples of the white pigment include metal oxides such as titanium oxide, aluminum oxide, zinc oxide, zirconium oxide, magnesium oxide, and the like; hollow fillers such as glass balloons, glass beads, and the like; and additionally, barium sulfate, zinc sulfate, barium titanate, aluminum nitride, boron nitride, and antimony oxide. Titanium oxide has high optical reflectivity and concealing properties, and is therefore preferable. Furthermore, aluminum oxide, zinc oxide, and barium titanate have high optical reflectivity of a UV region, and are therefore preferable. The average particle size or shape of the white pigment is not restricted, but the average particle diameter is within a range of 0.05 to 10.0 μm and preferably within a range of 0.1 to 5.0 μm. Furthermore, surface treatment of the white pigment can be performed using a silane coupling agent, silica, aluminum oxide, and the like.

A thermally conductive filler or an electrically conductive filler is added to the cured product for the purpose of imparting thermal conductivity/electrical conductivity thereto, and specific examples include: a metallic fine powder such as gold, silver, nickel, copper, or aluminum; a fine powder such as ceramic, glass, quartz or organic resin, the surface thereof on which a metal such as gold, silver, nickel, or copper is deposited or plated; a metallic compound such as aluminum oxide, magnesium oxide, aluminum nitride, boron nitride or zinc oxide or the like; and graphite, and mixtures of two or more of these. When electrical insulation is required for the present composition, a metal oxide-based powder or a metal nitride-based powder is preferable, and in particular, an aluminum oxide powder, a zinc oxide powder, or an aluminum nitride powder is preferable and combinations of type, particle diameter, and particle shape and the like can be used according to these thermal conductivity/electrical conductivity requirements.

Phosphor is a component that is blended to convert the emission wavelength from a light source (optical semiconductor element) when the cured product is used as a wavelength conversion material. There are no particular limitations to this phosphor, with examples thereof including yellow, red, green, and blue light phosphors, which include oxide phosphors, oxynitride phosphors, nitride phosphors, sulfide phosphors, oxysulfide phosphors, and the like, that are widely used in light emitting diodes (LED).

Silicone microparticles include non-reactive silicone resin microparticles and silicone elastomer microparticles, but silicone elastomer microparticles are suitably exemplified from the viewpoint of improving cured product flexibility or stress relief properties.

For the purpose or the like of stably blending the functional filler above in the present composition, the filler surface may be treated using a specific surface treatment agent in the range of 0.1 to 2.0 mass %, 0.1 to 1.0 mass %, or 0.2 to 0.8 mass % of the total mass of component (C). Examples of these surface treatment agents include, methylhydrogen polysiloxane, silicone resins, metal soaps, silane coupling agents, perfluoroalkyl silanes, as well as fluorine compounds such as perfluoroalkyl phosphate ester salts.

The content of (C) is not restricted, and depending on the purpose of use of the curable silicone composition of the present invention, it may be preferable not to substantially add (C). On the other hand, from the perspective of improving the hardness and mechanical strength of the resulting cured product and imparting functionality such as phosphor, a content in the range of 0 to 2000 parts by mass, in the range of 0 to 1500 parts by mass, or in the range of 0 to 1000 parts by mass is preferable relative to component (A) (100 parts by mass) described above.

Component (C) may be of any particle diameter, but if gap fill properties are to be imparted to the composition while hot-melted (melted with heat), an average particle size of 50 μm or less is preferably used, and if the amount of component (C) to be added is to be increased to the extent possible from the viewpoint of imparting functionality, combining of different particle diameters in order to improve the packing property of the filler is preferable.

### Other Additives

In addition to the component described above, a material conventionally known in the field may be added to the curable silicone composition of the present invention as an additive that may be used in a silicone composition, and examples of additives that may be used include, but are not limited to, those described below.

The composition of the present invention may contain an adhesion imparting agent so long as the object of the present invention is not impaired. Such adhesion imparting agents are common to components suitably exemplified by the present applicant in the international patent application (PCT/JP2020/ 12027), and reaction mixtures of epoxy group-containing organoalkoxysilane and amino group-containing organoalkoxysilane disclosed in Japanese Unexamined Patent Application S52-8854 and Japanese Unexamined Patent Application H10-195085, and particularly carbasilatrane derivatives having a silicon atom-bonded alkoxy group or silicon-bonded alkenyl group in a molecule, silatrane derivatives having an alkoxysilyl group-containing organic group, and the like can be preferably used in addition to 3-glycidoxypropyltrimethoxysilane and other silane compounds, organosiloxane oligomers, and alkyl silicates. These components may be used individually or in combination of two or more types, and by using two or three types together, greatly improving the adhesiveness and the like may be possible. Furthermore, in order to simultaneously impart melt flowability and ring-opening polymerizability to the present composition, cyclic trisiloxanes such as cyclic 1,1,3,3,5,5-hexamethyltrisiloxane, cyclic 1,3,5-triphenyl-1,3,5-trimethyltrisiloxane, cyclic 1,1,3,3,5,5-hexaphenyltrisiloxane, and the like, which are the same as component B2 described above, may be further added.

Furthermore, the composition may contain, as other optional components, heat resistant agents such as cerium oxide, cerium dimethyl silanolate, fatty acid cerium salt, cerium hydroxide, zirconium compound, and the like; and dyes, pigments other than white, flame retardant agents, and the like may be contained as long as the purpose of the present invention is not impaired.

On the other hand, since the composition of the present invention is intended to be organic solvent free, no use whatsoever of acetone, toluene, xylene, or the like organic solvent is preferable. Specifically, in the curable silicone composition according to the present invention, the content of the organic solvent, including organic solvent derived from the raw materials such as for component A), is less than 5% by mass of the entire composition, preferably less than 1% by mass, and is in particularly preferably less than 0.1% by mass. In addition, the composition of the present invention is preferably cured substantially only by component (B1), and after reacting, component (B1) preferably does not participate in side reactions or is removed from the cured product through volatilization or the like. Therefore, in the composition of the present invention, the content of the curing catalyst and the crosslinking agent other than (B1) is preferably less than 1% by mass, more preferably less than 0.1% by mass of the entire composition, and in particular preferably, an additional curing catalyst or crosslinking agent is not intentionally added.

The curable silicone composition according to the present invention can be produced as a granular composition by powder-mixing component (A) and component (B) and other optional components at a temperature lower than the softening point of component (A). The powder mixer or grinder used in the present manufacturing method is not limited, and examples include: a uniaxial or biaxial continuous mixer, a twin roller mixer, a ROSS mixer, a Hobart mixer, a dental mixer, a planetary mixer, a kneader mixer, a cutter mill, a free speed mill, a laboratory mill, a small grinder, and a Henschel mixer, and preferably, a laboratory mill, a small grinder, or a Henschel mixer.

The curable silicone composition according to the present invention can be molded in the form of granules, pellets, or sheets depending on the manufacturing process. When used as pellets, the composition can be efficiently produced by tableting the granulated present composition. A “pellet” may also be referred to as a “tablet.” The shape of the pellet is not limited, but is usually spherical, elliptical spherical, or cylindrical. The size of the pellet is not limited, and for example, has an average particle diameter or a circle equivalent diameter of 500 μm or more.

The composition may be molded into a sheet and used. For example, a sheet made of a curable silicone composition having an average thickness of 100 to 1,000 μm is advantageous in that it has hot-melt properties and heating-curability at high temperatures, and so in particular, demonstrates excellent workability and melting characteristics when used in compression molding or the like. Such a sheet-like composition may be produced by integrating the curable granular composition obtained by the aforementioned method with a uniaxial or biaxial continuous kneading machine at low temperatures, then making it to a prescribed thickness through two rollers or the like.

Since the present composition has hot-melt properties, use by heating and melting using a twin-screw extruder or the like, or use by filling a dispenser cartridge are feasible. Note that as with the curable silicone composition with hot-melt properties product (DOWSIL™ EA-4600 silicone adhesive), use with a hot dispensing method in which a heated dispenser is used to dispense is feasible.

From the perspective of transport and the like, the curable silicone composition after molding may be retained between base materials provided with a release layer and used as a peelable laminate. For example, in the case of a curable phosphor sheet composed of a curable silicone composition, the sheet can be laminated between plastic films provided with a release layer (for example, a release film composed of PET film, or the like) and arbitrarily cut into a form that can be used and the peelable film can be peeled off when used.

The curable silicone composition according to the present invention can suitably be obtained by a manufacturing method including steps 1 to 3 below. Here, the following steps 1 to 3 are preferably dry processes that essentially do not use any organic solvent.
Step 1: a step of mixing the component (B1) and component (B2) to obtain a condensation reaction catalyst containing mixture.
Step 2: a step of mechanically mixing component (A) and other optional components with the condensation reaction catalyst containing the mixture obtained in step 1 to obtain a curable silicone composition.
Step 3: a step of molding the curable silicone composition obtained in step 2.

The conditions for curing the curable silicone composition of the present invention are not particularly limited, but curing by a method including at least the following steps (I) to (III) involving molding is particularly preferred.
(I) a step involving heating to a temperature of 100° C. or higher to melt the present composition;
(II) a step involving injecting the curable silicone composition obtained in step (I) into a mold or a step involving distributing the curable silicone composition obtained in step (I) to a mold by clamping; and
(III) a step involving curing the curable silicone composition injected in the step (II).

The curing conditions for the curable silicone composition of the present invention are not particularly limited, but heating is preferably performed in the range of room temperature to 200° C., more preferably 80° C. to 170° C. Note that since the condensation reaction catalyst that is (B1) is activated during heating and melting, after heating and melting, a cured product can be formed by proceeding with the curing reaction after molding by any method.

### Use of Composition

The present composition has hot-melt properties, flowability while melted (hot-melt), and superior workability and curability, making it preferable as an encapsulant or underfill agent for semiconductors, an encapsulant or underfill agent for power semiconductors such as SiC, GaN, and the like, an encapsulant or light reflecting material for optical semiconductors such as light emitting diodes, photodiodes, phototransistors, laser diodes, and the like, or an electrical and electronic adhesive, potting agent, protecting agent, and coating agent. Furthermore, a sheet of this composition can be used as a curable fluorescent sheet, film adhesive, or as a stress buffer layer between two base materials with different coefficients of linear expansion.

In addition, since the present composition has hot-melt properties, the composition is also suitable as a material for transfer molding, compression molding, or injection molding, as well as an encapsulant for semiconductors using a mold underfill method or a wafer molding method during molding. In particular, the curable silicone composition according to the present invention can be suitably used for the purpose of obtaining a cured product by transfer molding.

### Cured Product and Laminate Body Containing the Same

A cured product obtained by curing the curable silicone composition according to the present invention is suitable as a member used in electronic components, semiconductor devices, or optical semiconductor devices. The curable silicone composition according to the present invention can form a cured product in a desired shape on a base material by means of transfer molding or the like. Therefore, a cured product according to the present invention is useful as an electronic component, a semiconductor device, an optical semiconductor device, or a member thereof. As described above, the curable silicone composition of the present invention may be in the form of a tablet, pellet, sheet, or film molded product, and may be used by curing or molding, or arranged as a member for electronic components, semiconductor devices, or optical semiconductor device members.

The cured product obtained by curing the curable silicone composition of the present invention has no particular limitations on applications, but can be suitably used as a component for electronic components, semiconductor devices, and optical semiconductor devices, and can be suitably used as a sealing material for semiconductor elements and IC chips and the like, or as an adhesive, bonding member, or sealant for semiconductor devices, and is particularly suitable for applications requiring high heat resistance and light resistance.

The semiconductor device provided with a member containing the cured product obtained by curing the curable silicone composition of the present invention is not particularly limited, but is preferably a light emitting semiconductor device, which is a light emitting/optical device, an optical member for displays, a member for solar panels, and in particular, is used as a sealing material, casing material, or adhesive member for these devices or the like. Furthermore, the cured product of the present invention has excellent coloring resistance at high temperatures, and therefore is more preferably used as a sealing material, case material, or adhesive member used in electronic materials where transparency and light/heat resistance are important.

### EXAMPLES

The curable silicone composition of the present invention and manufacturing method thereof are described below in detail using Embodiments and comparative examples. Note that in the following description, Me, Vi, and Ph in the chemical formula represent methyl groups, vinyl groups, and phenyl groups, respectively. The curable silicone compositions of examples and comparative examples were molded into tablets to prepare cured sheet samples using the following methods. In addition, the melt curability (flow curability), moldability, and light reflectance of the cured product sheet/wavelength conversion using a phosphor sheet/light diffusion/light transmittance were measured by the following methods. The measurement results are shown in Table 2 below.

### Molding into Tablets

Powder (=solid) in mixture form was pulverized and stirred based on the component and mix conditions indicated for each example and comparative example (Table 2 below) in a mixer (manufactured by Osaka Chemical Co., Ltd. trade designation Labomill (disposable container PN-M21): rotation speed 20,000 rpm) to prepare a curable silicone composition. Each of the compositions (powder mixture) obtained was molded into tablets having a length of 1-32 mm and a diameter of 3-16 mm using a tablet molding machine (manufactured by Ichihashi Seiki, trade designation Handtab).

### Preparation of Cured Sheet Sample

The tablets of each example and comparative example were pressure-pressed at 130° C. for 15 minutes in a mold of the required thickness, and then cured in an oven at 150° C. for 1 hour to prepare a sheet-like cured product sample.

### Measurement of Shore D Hardness

The hardness was measured using an automatic rubber hardness tester P2 manufactured by Kobunshi Keiki.

### Density Measurement

The density was measured using an XP-105 analytical balance and a density determination kit manufactured by Mettler Toledo.

### Measurement of Glass Transition Temperature

Measured using DSC2500, a thermal analysis system from TA Instruments.

### Measurement of Coefficient of Linear Expansion

Measured using a TMA7100 thermomechanical analyzer manufactured by Hitachi High-Tech Science. The coefficient of linear expansion at temperatures below the glass transition point is indicated by α1 (ppm), and the coefficient of linear expansion at temperatures above the glass transition point is indicated by α2 (ppm).

### Melt Curability (Flow Curability)

Measured in accordance with ASTM D5289 and ISO 6502 using Premier MDR, which is a Moving Die Rheometer (MDR) manufactured by Alpha Technologies.

Frequency: 100 cycle/minute (1.66 Hz), vibration angle +/−0.5 degrees

Measurements were made at 130° C. for 15 minutes.

With the minimum torque value ML at 1 dNm or less, if the time (TS1 value) required for the torque value to rise from the minimum torque value to 1 dNm is 180 seconds or less, the melt curability of the obtained cured product is evaluated as “good” and otherwise is evaluated as “poor curing” or “delayed curing.” In addition, the maximum torque value (MH) was recorded and the time to reach 50% of this torque value was recorded as T50 (seconds).

### Moldability

The base temperature of the mold was set using a G-CUBE (MPC-06M)) manufactured by Apic Yamada so as to achieve a resin temperature of 130° C. and transfer molding (130° C. for 5 minutes after clamping) was performed in a 57 mmW, 50 mmD, 0.25 mmT lead frame (TD-3535-01-1) manufactured by Apic Yamada using 4 g of 13 mm diameter resin in a pattern that was 50 mmW, 47 mmD and two resin heights of 0.45 mm and 0.40 mm, and molding was judged to be good if adhesion to the base material was favorable with no peeling and molding in the shape of the metal mold was feasible.

### Complex Viscosity at 130° C.

Using a rheometer MCR301 manufactured by Anton Paar, the minimum value of the complex viscosity at a strain of 3% and an amplitude of 1 Hz for a thin tablet prepared with a diameter of 10 mm and height of 1 mm was measured using a parallel plate with a diameter of 10 mm.

### Light Reflectance

The light reflectance of the prepared cured sheet was measured using a spectrophotometer CM-5 manufactured by Konica Minolta, Inc.

### Wavelength Conversion using a Phosphor Sheet

A cured sheet containing a phosphor was irradiated with 447 nm blue LED light using the fluorescent film test system DF-500A manufactured by Otsuka Electronics Co., Ltd., and the chromaticity coordinates (x, y) and relative color temperature (K) obtained by wavelength conversion using this sheet were measured.

### Light Diffusion Characteristics

The light diffusing characteristics of the cured sheet were measured with a Genesia Gonio/Far Filed Profiler manufactured by Genesia Corporation, using a bidirectional transmittance distribution function of 45 degrees. When the light transmitted light intensity is perpendicularly incident on the measurement sample surface, that is, when the linear transmitted light intensity is 1, if the reception light intensity at the position where the light receiving unit is tilted 45 degrees with respect to the incident optical axis center on the measurement sample that is 0.65 or more, light diffusion is evaluated as “O” or favorable, and if the reception light intensity is less than 0.65, light diffusing is evaluated as “x”.

### Light transmittance

The light transmittance of the cured product sheet was measured using a V770 UV-Vis-NIR spectrophotometer manufactured by JASCO Corporation equipped with a 150 mmφ integrating sphere unit.

### (A) Solid Organopolysiloxane Resin

In the examples and comparative examples, the solid organopolysiloxane resin was composed of the siloxane units (mol%) indicated in Table 1 below, and resins A-a to A-d having the weight average molecular weight (Mw), Tg (C), and hydroxyl group content (% by mass) were used. Note, the siloxane units expressed by D(Me)₂, DMePh, D(Ph)₂, T(Me), and T(Ph) in the table are respectively Si(Me)₂O_{2/2} and Si(Me)(Ph)O_{2/2}, Si(Ph)₂O_{2/2}, Si(Me)O_{3/2}, and Si(Ph)O_{3/2}. These are all organopolysiloxane resins with hot-melt properties containing OH groups and phenyl groups.

TABLE 1

| | | OH | Tg | | | | | |
|---|---|---|---|---|---|---|---|---|
| Resin | Mw | (wt %) | (° C.) | D(Me)₂ | DMePh | D(Ph)₂ | T(Me) | T(Ph) |
| A-a | 1700 | 0.5 | 55 | 0 | 0 | 0 | 0 | 100 |
| A-b | 3820 | 0.5 | 58 | 5 | 0 | 0 | 47 | 48 |
| A-c | 3670 | 0.5 | 32 | 15 | 0 | 0 | 40 | 45 |
| A-d | 7250 | 0.5 | 55 | 0 | 5 | 10 | 45 | 40 |

### (B) Superbasic Catalyst/Mixture for Condensation Reaction

In the examples and comparative examples, the following catalyst B was used. In addition, diazabicycloundecene (1,8-diazabicyclo[5.4.0]undec-7-ene) is hereinafter referred to as “DBU”. DBU is liquid and volatile at room temperature and the % in parentheses is the % by mass of DBU. In addition, catalysts B-c to B-h are pre-mixtures corresponding to component (B) in the present invention.
Catalyst B-a′: DBU (100%)
Catalyst B-b′: Toluene solution of DBU (10%)
Catalyst B-c: Mixture (1%) of DBU with cyclic phenylmethylsiloxane (average degree of polymerization: 4)
Catalyst B-d: mixture (73%) of DBU with polysiloxane having the average compositional formula HO—(SiPhMe—O)₅—H
Catalyst B-e: mixture (27%) of DBU with polysiloxane having the average compositional formula HO—(SiPhMe₂—O)₁₂—H
Catalyst B-f: mixture (6%) of DBU with polysiloxane having the average compositional formula HO—(SiMe₂—O)₃₀—SiMe₃
Catalyst B-g: mixture (5%) of DBU with cyclic dimethylsiloxane (average degree of polymerization: 4)
Catalyst B-h: mixture (5%) of DBU with cyclic phenylmethylsiloxane (average degree of polymerization 4)

### (C) Solid Particles

In the examples and comparative examples, the following powders were used as solid particles. The alphanumeric characters at the end of each component are product numbers.
Powder C-as: spherical silica FB-5SDC with an average particle size of 4 μm manufactured by Denka Company Limited
Powder C-bs: spherical silica SE-15K with an average particle size of 16 μm manufactured by Tokuyama Corporation
Powder C-cs: spherical silica SE-30K with an average particle size of 25 μm manufactured by Tokuyama Corporation
Powder C-ds: spherical silica UF-725 with an average particle size of 7 μm manufactured by Tokuyama Corporation
Powder C-es: spherical silica FB-7SDC with an average particle size of 6 μm manufactured by Denka Company Limited
Powder C-fs: spherical silica ST-7010-2 with an average particle size of 10 μm manufactured by Nippon Steel & Sumikin Materials Co., Ltd.
Powder C-gs: spherical silica ST-7011-3 with an average particle size of 12 μm manufactured by Nippon Steel & Sumikin Materials Co., Ltd.
Powder C-hf: milled fiber EFDE 50-01 with an average fiber length of 50 μm and a fiber diameter of 11 μm manufactured by Central Glass Fiber Co., Ltd.
Powder C-if: aminosilane-treated milled fiber EFDE50-31 with an average fiber length of 50 μm and a fiber diameter of 11 μm manufactured by Central Glass Fiber Co., Ltd.
Powder C-jf: milled fiber EFDE75-01 with an average fiber length of 75 μm and a fiber diameter of 11 μm manufactured by Central Glass Fiber Co., Ltd.
Powder C-kf: milled fiber EFDE 90-01 with an average fiber length of 90 μm and a fiber diameter of 6 μm manufactured by Central Glass Fiber Co., Ltd.
Powder C-lp: Carbon black SUNBLACK235 manufactured by Asahi Carbon Co., Ltd.
Powder C-mp: Titanium oxide SX-3103 manufactured by Sakai Chemical Industry Co., Ltd.
Powder C-np: YAG yellow phosphor NYAG4454S manufactured by INTEMRTIX
Powder C-os: spherical silica FB-3SDC with an average particle size of 3 μm manufactured by Denka Company Limited
Powder C-ps: spherical alumina AZ4-10 with an average particle size of 3 μm manufactured by Nippon Steel & Sumikin Materials Co., Ltd.
Powder C-qs: spherical silica S4080-5 with an average particle size of 23 μm manufactured by Nippon Steel & Sumikin Materials Co., Ltd.

### Additives

In examples and comparative examples, the following Additives 1 to 3 were used for the purpose of functions such as an adhesion-imparting agent.
Additive 1: 3-glycidoxypropyltrimethoxysilane
Additive 2: Carbasilatrane derivative expressed by the following structural formula:

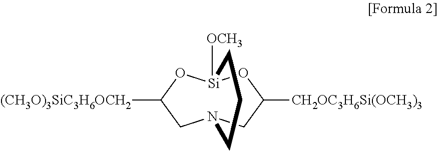

Additive 3: 3-glycidoxypropyltrimethoxysilane
Additive 4: Cyclic-1,1,3,3,5,5-hexamethyltrisiloxane (D3)

### Comparative Examples 1 to 2, Examples 1 to 7

Resin A having the composition indicated in Table 2 below was placed in a mixer, pulverized, and stirred for 15 seconds, cooled, and then this operation was repeated a second time. Powder C and catalyst B were added to the resulting powder, pulverized, and stirred for 15 seconds, cooled, and this operation is repeated a second time to prepare a curable silicone composition in the form of a powder mixture. The composition was molded into a tablet, and the melt curability and the like were evaluated using the methods described above. The DBU concentration in the composition is shown in DBU (ppm).

TABLE 2

| | Comparative | Comparative | | |
|---|---|---|---|---|
| | Exam- | Exam- | Exam- | Exam- |
| Mass g | ple 1 | ple 2 | ple 1 | ple 2 |
| Resin A-a | | | | |
| Resin A-b | | | | |
| Resin A-c | | | | |
| Resin A-d | 10.00 | 15.00 | 10.00 | 10.00 |
| Catalyst B-a′ | 0.062 | | | |
| Catalyst B-b′ | | 0.181 | | |
| Catalyst B-c | | | 0.197 | 0.301 |
| Additive 1 | | | | |
| Powder C-as | | | | |
| DBU, ppm | 3090* | 1192* | 193 | 292 |
| Shore D | | | | |
| Hardness | | | | |
| Density | | | | |
| Coefficient of linear | | | | |
| expansion α1 | | | | |
| Coefficient of linear | | | | |
| expansion α2 | | | | |
| Minimum complex | | | | |
| viscosity Pa · s | | | | |
| at 130° C. | | | | |
| MDR measurement | | | | |
| results (130° C.) | | | | |
| TS1, sec | 30.8 | 179.4 | 98 | 75 |
| T50, min | 2.5 | 8.53 | | |
| ML, dNm | 0 | 0 | 0 | 0 |
| MH, dNm | 182.6 | 177.0 | 108.81 | 144.18 |
| Melt curability | <Good> | <Good> | Favorable | Favorable |

| | Exam- | Exam- | Exam- | Exam- | Exam- |
|---|---|---|---|---|---|
| Mass g | ple 3 | ple 4 | ple 5 | ple 6 | ple 7 |
| Resin A-a | | | 10.00 | | |
| Resin A-b | 15.01 | 10.00 | | | |
| Resin A-c | | | | | 10.02 |
| Resin A-d | | | | 10.00 | |
| Catalyst B-a′ | | | | | |
| Catalyst B-b′ | | | | | |
| Catalyst B-c | 0.299 | 0.399 | 0.402 | 0.401 | 0.404 |
| Additive 1 | 0.302 | | | | |
| Powder C-as | | 10.00 | 10.01 | 10.00 | 10.01 |
| DBU, ppm | 192 | 196 | 197 | 197 | 198 |
| Shore D | 83 | 90 | | 88 | 88 |
| Hardness | | | | | |
| Density | 1.25 | 1.58 | | 1.57 | 1.56 |
| Coefficient of linear | 100 | 57 | | 50 | |
| expansion α1 | | | | | |
| Coefficient of linear | 146 | 81 | | 80 | |
| expansion α2 | | | | | |
| Minimum complex | 31 | 319 | 199 | 44 | 134 |
| viscosity Pa · s | | | | | |
| at 130° C. | | | | | |
| MDR measurement | | | | | |
| results (130° C.) | | | | | |
| TS1, sec | 51 | 33 | 114 | 77 | 96 |
| T50, min | 2.45 | 1.56 | 7.13 | 4.84 | 2.44 |
| ML, dNm | 0 | 0 | 0 | 0 | 0 |
| MH, dNm | 163.73 | 177.15 | 136.96 | 171.19 | 17.15 |
| Melt curability | Favor- | Favor- | Favor- | Favor- | Favor- |
| | able | able | able | able | able |

*Curing was poor at DBU concentrations lower than this level.

In the examples, by using a cyclic phenylmethylsiloxane that does not volatilize at room temperature, the DBU catalyst is dispersed in the silicone, and as in Examples 1 and 2, even if the DBU content is less than ⅕ of that in Comparative Example 2, the melt-curing properties can be improved. Furthermore, in the composition containing powder C, the melt curability was favorable even when the addition of the catalyst was suppressed to about 1/15 (around 200 ppm) compared to Comparative Example 1. Furthermore, from a comparison of Examples 3 and 4, the composition containing powder C markedly increases the hardness of the cured product and decreases the coefficient of linear expansion. Thus, indicating that compositions suitable for solid sealing material for semiconductors similar to epoxy based molding compounds can be designed. Note that the reason why the amount of DBU added can be reduced is thought to be that DBU forms coordinate bonds with cyclic phenylmethylsiloxane due to pre-mixing, which inhibits adsorption to solid (powder) surfaces and the like.

In Comparative Examples 1 and 2, by setting the DBU concentration to an extremely high addition amount (over 1000 ppm), good melt curability was barely achieved, while curing failed at addition amounts lower than this level such that sufficient melt curability was not achieved. Furthermore, since the DBU concentration is too high, there is concern that side reactions before and after curing will adversely affect the hardness and stability of the cured product.

### Examples 8 to 18

A curable silicone composition was prepared in the form of a powder mixture in the same manner as in Example 1 except that the compositions were as indicated in Table 3 below. The composition was molded into a tablet, and the melt curability and the like were evaluated using the methods described above. The DBU concentration in the composition is shown in DBU (ppm).

TABLE 3

| | Example No. | | | |
|---|---|---|---|---|
| Mass g | 8 | 9 | 10 | 11 |
| Resin A-d | 10.00 | 10.01 | 15.00 | 10.00 |
| Catalyst B-d | 0.026 | | | |
| Catalyst B-e | | 0.015 | 0.010 | |
| Catalyst B-f | | | | 0.065 |
| Catalyst B-g | | | | |
| Powder C-as | 10.01 | 10.01 | | 10.00 |
| DBU ppm | 951 | 203 | 181 | 203 |
| Minimum complex | 81 | 1400 | 81 | 760 |
| viscosity Pa · s at 130° C. | | | | |
| MDR measurement | | | | |
| results (130° C.) | | | | |
| TS1, sec | 180 | 42 | 70 | 32 |
| T50, min | 10.889 | 2.34 | 3.86 | 1.64 |
| ML, dNm | 0 | 0 | 0 | 0 |
| MH, dNm | 119.95 | 164.93 | 165.81 | 163.96 |
| Melt curability | Favor- | Favor- | Favor- | Favor- |
| | able | able | able | able |

| | Example No. | | | |
|---|---|---|---|---|
| Mass g | 12 | 13 | 14 | 15 |
| Resin A-d | 10.00 | 15.00 | 15.00 | 10.00 |
| Catalyst B-d | | | | |
| Catalyst B-e | | | | |
| Catalyst B-f | 0.299 | 0.049 | 0.229 | |
| Catalyst B-g | | | | 0.080 |
| Powder C-as | 10.00 | | | 10.00 |
| DBU ppm | 922 | 204 | 942 | 199 |
| Minimum complex | 126000 | 57 | 3300 | 590 |
| viscosity Pa · s at 130° C. | | | | |
| MDR measurement | | | | |
| results (130° C.) | | | | |
| TS1, sec | 11 | 61 | 24 | 56 |
| T50, min | 0.45 | 3.55 | 0.84 | 2.99 |
| ML, dNm | 0 | 0 | 0 | 0 |
| MH, dNm | 173.11 | 174.99 | 168.79 | 170.47 |
| Melt curability | Favor- | Favor- | Favor- | Favor- |
| | able | able | able | able |

| | Example No. | | |
|---|---|---|---|
| Mass g | 16 | 17 | 18 |
| Resin A-d | 10.00 | 15.00 | 15.00 |
| Catalyst B-d | | | |
| Catalyst B-e | | | |
| Catalyst B-f | | | |
| Catalyst B-g | 0.397 | 0.064 | 0.298 |
| Powder C-as | 10.00 | | |
| DBU ppm | 973 | 212 | 974 |
| Minimum complex | 140000 | 61 | 400 |
| viscosity Pa · s at 130° C. | | | |
| MDR measurement | | | |
| results (130° C.) | | | |
| TS1, sec | 13 | 81 | 27 |
| T50, min | 0.52 | 4.67 | 1.14 |
| ML, dNm | 0 | 0 | 0 |
| MH, dNm | 165.32 | 169.7 | 175.24 |
| Melt curability | Favor- | Favor- | Favor- |
| | able | able | able |

In each example, it was confirmed that by pre-mixing DBU with various cyclic or chain siloxanes, good melt-curing properties can be achieved even with compositions containing powders and DBU concentrations below 1000 ppm. Note that it was found that each composition had a different curing speed due to the coordination ability with DBU being different according to the type of siloxane. Therefore, by designing the type of siloxane premixed with DBU and the DBU concentration, design for a desired curing speed can be achieved.

### Examples 19 to 26: Black Light Shielding Materials

A curable silicone composition was prepared in the form of a powder mixture in the same manner as in Example 1 except that the compositions were as indicated in Table 4 below. The composition was molded into a tablet, and the melt curability and the like were evaluated using the methods described above. These compositions contain resin, spherical powder, fibrous powder, and black pigment (carbon black), and are designed so that the cured product thereof will be a light-shielding material. The DBU concentration in the composition is shown in DBU (ppm).

TABLE 4

| | Example No. | | | |
|---|---|---|---|---|
| Mass g | 19 | 20 | 21 | 22 |
| Resin A-d | 8.00 | 8.01 | 8.00 | 8.00 |
| Catalyst B-h | | | | |
| Catalyst B-g | 0.562 | 0.555 | 0.559 | 0.565 |
| Additive 2 | 0.296 | 0.297 | 0.302 | 0.295 |
| Additive 1 | 0.304 | 0.305 | 0.305 | 0.306 |
| Additive 3 | 0.149 | 0.156 | 0.148 | 0.155 |
| Spherical powder | Powder | Powder | Powder | Powder |
| | C-gs | C-fs | C-es | C-ds |
| | 16.67 | 16.67 | 16.67 | 16.67 |
| Fibrous powder | Powder | Powder | Powder | Powder |
| | C-hf | C-hf | C-hf | C-hf |
| | 1.41 | 1.42 | 1.42 | 1.41 |
| Black pigment powder | 2.50 | 2.50 | 2.50 | 2.50 |
| Powder C-lp | | | | |
| DBU ppm | 188 | 186 | 187 | 189 |
| Filler wt % | 68.9 | 68.8 | 68.8 | 68.8 |
| Hardness Shore D | 92 | 92 | 91 | 92 |
| Density g/cm³ | 1.78 | 1.78 | 1.78 | 1.78 |
| Coefficient of linear | 35 | 36 | 33 | 33 |
| expansion α1 | | | | |
| Coefficient of linear | 75 | 86 | 59 | 79 |
| expansion α2 | | | | |
| Minimum complex | 2000 | 2400 | 1400 | 2500 |
| viscosity Pa · s at 130° C. | | | | |
| MDR measurement | | | | |
| result (130° C.) | | | | |
| Ts1, sec | 122.46 | 133.35 | 132.96 | 91.58 |
| ML, dNm | 0.04 | 0.01 | 0.02 | 0.02 |
| MH, dNm | 52.7 | 64.82 | 63.89 | 74.19 |
| Melt curability | Favorable | Favorable | Favorable | Favorable |
| Total light transmittance | 0.0% | 0.0% | 0.0% | 0.0% |
| at 100 μm thickness | | | | |
| Formability | Favorable | Favorable | Favorable | Favorable |
| | Example No. | | | |
| Mass g | 23 | 24 | 25 | 26 |
| Resin A-d | 8.01 | 8.00 | 8.00 | 4.80 |
| Catalyst B-h | | | | 0.102 |
| Catalyst B-g | 0.551 | 0.561 | 0.562 | |
| Additive 2 | 0.301 | 0.304 | 0.302 | 0.183 |
| Additive 1 | 0.304 | 0.304 | 0.301 | 0.187 |
| Additive 3 | 0.148 | 0.147 | 0.149 | 0.093 |
| Spherical powder | Powder | Powder | Powder | Powder |
| | C-as | C-as | C-as | C-bs |
| | 16.67 | 16.67 | 16.67 | 23.50 |
| Fibrous powder | Powder | Powder | Powder | |
| | C-kf | C-jf | C-hf | |
| | 1.41 | 1.41 | 1.42 | |
| Black pigment powder | 2.51 | 2.50 | 2.50 | 2.66 |
| Powder C-lp | | | | |
| DBU ppm | 184 | 188 | 188 | 162 |
| Filler wt % | 68.9 | 68.8 | 68.8 | 83.0 |
| Hardness Shore D | 92 | 91 | 91 | 95 |
| Density g/cm³ | 1.78 | 1.78 | 1.78 | 1.93 |
| Coefficient of linear | 33 | | 31 | 16 |
| expansion α1 | | | | |
| Coefficient of linear | 72 | | 67 | 32 |
| expansion α2 | | | | |
| Minimum complex | 1600 | 1400 | 1700 | 33900 |
| viscosity Pa · s at 130° C. | | | | |
| MDR measurement | | | | |
| result (130° C.) | | | | |
| Ts1, sec | 113.4 | 113.4 | 113.4 | 45.46 |
| ML, dNm | 0 | 0 | 0 | 0.36 |
| MH, dNm | 58.23 | 58.23 | 58.23 | 93.15 |
| Melt curability | Favorable | Favorable | Favorable | Favorable |
| Total light transmittance | 0.0% | 0.0% | 0.0% | 0.0% |
| at 100 μm thickness | | | | |
| Formability | Favorable | Favorable | Favorable | Favorable |

In each example, even with a composition containing a spherical powder, a fibrous powder, and a black pigment, a DBU concentration of 200 ppm or less had good melt-hardening properties, and had good curing speed, mechanical strength, and molding properties. Thus, a hot-melt composition providing a cured product with excellent light-shielding properties was obtained.

### Examples 27 to 28: Adhesive for Black Light Shielding Materials

A curable silicone composition was prepared in the form of a powder mixture in the same manner as in Example 1 except that the compositions were as indicated in Table 5 below. The composition was molded into a tablet, and the melt curability and the like were evaluated using the methods described above. These compositions contain resin, spherical powder, fibrous powder, and black pigment (carbon black), and are designed so that the cured product thereof will be a light-shielding material. The DBU concentration in the composition is shown in DBU (ppm).

TABLE 5

Example No.

| Mass g | 27 | 28 |
|---|---|---|
| Resin A-c | 4.2 | 64.97 |
| Catalyst B-h | 0.12 | 1.783 |
| Additive 1 | 0.18 | 2.776 |
| Additive 2 | | 5.569 |
| Additive 3 | 0.09 | 1.392 |
| Additive 4 | 0.37 | |
| Spherical powder | Powder | Powder |
| | C-qs | C-qs |
| | 24.68 | 381.8 |
| Black pigment powder | 2.71 | 41.77 |
| Powder C-lp | | |
| DBU ppm | 190 | 178 |
| Filler wt % | 84.7 | 84.7 |
| Hardness Shore D | 95 | 94 |
| Density g/cm³ | 1.96 | 1.94 |
| Coefficient of linear | 14 | 14 |
| expansion α1 | | |
| Coefficient of linear | 32 | 33 |
| expansion α2 | | |
| Minimum complex viscosity | 18000 | 12000 |
| Pa · s at 130° C. | | |
| MDR measurement | | |
| result (130° C.) | | |
| Ts1, sec | 43 | 45 |
| ML, dNm | 0.6 | 0.4 |
| MH, dNm | 90 | 108 |
| Melt curability | Favorable | Favorable |
| Total light transmittance | 0.0% | 0.0% |
| at 100 μm thickness | | |
| Formability | Favorable | Favorable |

In each example, even with a composition containing a spherical powder and a black pigment, a DBU concentration of 200 ppm or less had good melt-hardening properties, and had good curing speed, mechanical strength, and molding properties. Thus, a hot-melt composition providing a cured product with excellent light-shielding properties was obtained.

### Adhesive Strength with Glass

Furthermore, the compositions according to Examples 27 and 28 were used to evaluate the initial and post temperature test adhesion to untreated/primer surface treated glass base material using the following method.

### <Evaluation>

0.1 g of the curable composition of Example 27 or Example 28 was sandwiched between Corning Eagle XG glass plates 25×75×1 and 5×5×1.1 mm so as to achieve a diameter of 5 mm and a thickness of 0.13 mm. This was heat cured at 150° C. for one hour, the portion protruding for the general shape was removed, and die shear strength was measured using a bond tester SS-30WD manufactured by Seishin Trading Co., Ltd.

The glass base material described above was immersed in a 20-fold diluted solution of Dow Toray primer APZ-6601 (solution primarily containing N-beta-aminoethyl-gamma-aminopropyltriethoxysilane), then dried at 80ºC for one hour (-treated with primer) and shown combined with results.

Furthermore, these base materials were tested at temperatures of −40° C. and 85° C. for 30 minutes using an Espec thermal shock tester TSA-73EH, and at a temperature of 85° C. and a humidity of 85% with an Espec constant temperature and humidity chamber PL-3J. Table 6 below indicates the results of a two-week environmental resistance test.

TABLE 6

| | Composition of | Composition of | Composition of |
|---|---|---|---|
| | Example 27 | Example 28 | Example 28 |
| Adhesion Strength | and Untreated | and Untreated | and APZ-6601 |
| (N/cm²) | Glass | Glass | Treated Glass |
| Initial | 920 N/cm² | 670 N/cm² | 710 N/cm² |
| 2 weeks after | 950 N/cm² | 660 N/cm² | 840 N/cm² |
| thermal shock test | | | |
| 2 weeks after | 850 N/cm² | 950 N/cm² | 820 N/cm² |
| constant temperature | | | |
| and humidity test | | | |

As indicated in Table 6, the cured product from curing the composition according to Examples 27 and 28 had superior initial adhesion to untreated glass/primer treated glass and also had very good adhesion reliability in impact tests and the like. In addition, exhibiting of favorable adhesion was confirmed even when combined with primer treatment.

### Examples 29 and 30: Optical Member

A curable silicone composition was prepared in the form of a powder mixture in the same manner as in Example 1 except that the compositions were as indicated in Table 7 below. The composition was molded into a tablet, and the melt curability and the like were evaluated using the methods described above. Example 29 is a white light diffuse reflective material containing titanium oxide (white pigment), and Example 30 is a phosphor sheet containing a yellow fluorescent substance and as indicated below, having favorable melt curability even at a DBU concentration of 1000 ppm or less and can provide a superior cured product with rapid curing, mechanical strength, moldability, and anticipated optical properties. The DBU concentration in the composition is shown in DBU (ppm).

TABLE 7

| | Example No. (design application) | |
|---|---|---|
| | 29 (white light diffuse | 30 (phosphor |
| Mass g | reflective material) | sheet) |
| Resin A-d | 8.00 | 8.00 |
| Catalyst B-g | 2.000 | 0.604 |
| Additive 2 | 0.305 | 0.306 |
| Additive 1 | 0.302 | 0.3 |
| Additive 3 | 0.101 | 0.101 |
| Powder C-as (spherical) | 7.00 | 7.00 |
| Powder C-hf (fibrous) | 1.84 | 1.84 |
| Powder C-mp (white pigment) | 12.01 | |
| Powder C-np (yellow phosphor) | | 12.00 |
| DBU ppm | 634 | 200 |
| Hardness Shore D | 91 | 91 |
| Density g/cm³ | 2.09 | 2.19 |
| Minimum complex viscosity | 2490 | 26500 |
| Pa · s at 130° C. | | |
| MDR measurement | | |
| result (130° C.) | | |
| Ts1, sec | 55 | 33 |
| T50, min | 3.66 | 2.34 |
| ML, dNm | 0 | 0 |
| MH, dNm | 86 | 93 |
| Melt curability | Favorable | Favorable |
| Formability | Favorable | Favorable |
| Reflectance at 0.2 mm thickness | 98.00% | |
| Chromaticity coordinates (x, y) | | (0.438, 0.526) |
| at 0.2 mm thickness | | |
| Relative color temperature | | 3748 |
| at 0.2 mm thickness, K | | |

In each example, even with compositions containing spherical powders, fibrous powders, white reflective materials, and phosphors, the DBU concentration was 1000 ppm or less, and having good melt curability was achieved. In addition, a hot-melt composition that achieves a cured product having superior curing speed, mechanical strength, moldability, and light-shielding properties can be obtained. In Example 29, a cured product exhibiting high reflectance was obtained, and in Example 30, the blue LED was efficiently converted by the phosphor, and a warm white color was obtained.

### Examples 31 and 32: Light Diffusing Plate

A curable silicone composition was prepared in the form of a powder mixture in the same manner as in Example 1 except that the compositions were as indicated in Table 8 below. The composition was molded into a tablet, and the melt curability and the like were evaluated using the methods described above. These compositions are designed as light diffusing materials, but the spherical alumina powder C-ps is also a functional particle of heat dissipation/thermal conductivity. The DBU concentration in the composition is shown in DBU (ppm).

TABLE 8

| | Example No. (design application) | |
|---|---|---|
| | 31 (light | 32 (light |
| | diffusing | diffusing |
| Mass g | material) | material) |
| Resin A-d | 13.00 | 13.004 |
| Catalyst B-g | 0.198 | 0.201 |
| Additive 2 | 0.102 | 0.101 |
| Additive 1 | 0.098 | 0.099 |
| Additive 3 | 0.051 | 0.053 |
| Powder C-os (Spherical) | 15.00 | 16.50 |
| Powder C-ps (Spherical) | 1.51 | |
| DBU ppm | 330 | 335 |
| Hardness Shore D | 90 | 91 |
| Density g/cm³ | 1.66 | 1.64 |
| Minimum complex viscosity | 9907 | |
| Pa · s at 130° C. | | |
| MDR measurement | | |
| result (130° C.) | | |
| Ts1, sec | 25.17 | 24.93 |
| T50, min | 1.43 | 1.34 |
| ML, dNm | 0.02 | 0.05 |
| MH, dNm | 170.73 | 171.22 |
| Melt curability | Favorable | Favorable |
| Formability | Favorable | Favorable |
| Transmittance % of 550 nm | 53.3096 | 56.1186 |
| at 0.2 mm thickness | | |
| Light diffusion at 0.2 mm thickness | Good (0.676) | Good (0.663) |
| Transmittance % of 550 nm | 45.5656 | 50.9551 |
| at 0.3 mm thickness | | |
| Light diffusion at 0.3 mm thickness | Good (0.685) | Good (0.682) |

By using a pre-mix of the condensation catalyst according to the present invention, even at a DBU concentration of 500 ppm or less, favorable melt curability is achieved, and a cured product with superior curing speed, mechanical strength, moldability, as well as optical properties of light transmittance and light diffusion can be achieved.

### Summary

By using a pre-mix of DBU and various liquid siloxanes as a condensation reaction catalyst and mixing with silicone having a glass transition point of 25° C. or higher, the interaction between DBU and powder and the like is inhibited. Regardless of the type and presence of functional powder, favorable melt curability is achieved at a relatively low DBU concentration. A hot-melt curable silicone composition and molded product (tablet) thereof that provides a cured product having superior curing speed, mechanical strength, transfer moldability, and superior physical functions achieved by functional fillers can be obtained. The composition requires substantially no organic solvent for manufacture and use and is suitable for organic solvent-free manufacturing and use processes. Conversely, when a premix of the same condensation reaction catalyst is not used, favorable melt curability cannot be achieved unless the concentration of DBU is excessive. Even if this can be achieved, side reactions such as unintended condensation of resins may occur before and after the curing reaction, and there is concern about deterioration of the cured product and functional deterioration over time. In the present invention, evaluation of melt curability using MDR and rheology measurements were performed at 130° C., but, needless to say, evaluation is also possible at 170° C.

The curable silicone composition with hot-melt properties according to the present invention may or may not contain functional fillers, and may contain spherical powders, fibrous powders, pigments (white pigments and black pigments), and thermally conductive fine particles and still achieve the effect of the invention. This composition may be used in the design of various functional materials, for example, as protective materials, encapsulants, adhesive materials (bonding materials), as well as light shielding materials, white reflective materials, phosphor sheets, light diffusing materials, heat dissipation and thermal conductive materials, and electrical conductive materials.

1. A curable silicone composition, comprising:
(A) an organopolysiloxane resin having a glass transition temperature (Tg) in a range of 25° C. to 130° C. containing a siloxane unit expressed by RSiO_{3/2} or SiO_{4/2} in the molecule, where R represents an alkyl group having 1 to 20 carbon atoms or an aryl group having 6 to 14 carbon atoms which may be substituted with a halogen atom, and at least one of a condensation reactive functional group and an aromatic functional group in the molecule; and
(B) a mixture comprising component (B1) and component (B2) below, pre-mixed at a mass ratio of 1:99 to 90:10;
(B1) a condensation reaction catalyst that is liquid at 25° C.,
(B2) a chain or cyclic organopolysiloxane that is liquid at 25° C. and has a degree of polymerization of siloxane in the range of 3 to 50;
wherein the overall composition is non-flowable at 25° C. while having hot-melt properties.

2. The curable silicone composition according to claim 1, wherein component (B1) is a volatile condensation reaction catalyst where the amount of a condensation reaction catalyst is 1000 ppm or less relative to the entire composition.

3. The curable silicone composition according to claim 1, wherein component (B1) is one or more type of condensation reaction catalyst selected from diazabicycloundecene (DBU), diazabicyclononane (DBN), diazabicyclooctane (DABCO), tetramethylguanidine (TMG), triazabicyclodecene (TBD), and N-methyltriazabicyclodecene (MTBD).

4. The curable silicone composition according to claim 1, further comprising:
(C) solid particles.

5. The curable silicone composition according to claim 4, wherein at least a portion of component (C) is one or more types selected from (CS) spherical solid particles, (CF) fibrous solid particles, and (CP) pigment or phosphor particles.

6. The curable silicone composition according to claim 1, wherein an organic solvent content is less than 5% by mass of the entire composition and an amount of curing catalyst and crosslinking agent other than component (B1) is less than 1% by mass of the entire composition.

7. The curable silicone composition according to claim 1, suitable for transfer molding.

8. The curable silicone composition according to claim 1, wherein the complex melt viscosity of the entire composition at 130° C. is 500,000 Pa·s or less, and the form is of a tablet, a pellet, a sheet, or film molded product.

9. The curable silicone composition according to claim 1, wherein the complex melt viscosity of the entire composition at 130° C. is 500,000 Pa·s or less, and the form is a cartridge for a dispenser filled with the curable silicone composition.

10. A cured product obtained by curing the curable silicone composition according to claim 1.

11. A peelable laminate, comprising:
a molded product of a base material provided with a peelable layer; and
the curable silicone composition according to claim 1.

12. A laminate body, comprising the a cured product of the cured curable silicone composition according to claim 1.

13. The laminate body according to claim 12, wherein the laminate body is an electronic component, a semiconductor device, an optical semiconductor device, or a member thereof.

14. A method for manufacturing the curable silicone composition according to claim 1, the method comprising:
1) a step of mixing component (B1) and component (B2) to obtain a mixture containing condensation reaction catalyst;
2) a step of-mixing component (A) and optionally other components and the mixture containing condensation reaction catalyst obtained in step 1) using mechanical force to obtain a curable silicone composition; and
3) a step of molding the curable silicone composition obtained in step 2);
wherein steps 1) to 3) are all dry steps where organic solvent is essentially not used.

15. A method for manufacturing a laminate body, the method comprising: forming a cured product by curing the curable silicone composition according to claim 1 on a base material using transfer molding.
